(19) United States
(12) Patent Application Publication
(10) Pub. No.: US 2025/0021025 A1
(43) Pub. Date: Jan. 16, 2025

(54) SUBSTRATE PROCESSING METHOD AND SUBSTRATE PROCESSING APPARATUS USING THE SAME

(71) Applicant: SAMSUNG ELECTRONICS CO., LTD., Suwon-si (KR)

(72) Inventors: Youngho HWANG, Suwon-si (KR); Sanghyun LIM, Suwon-si (KR); Youngkyun IM, Suwon-si (KR); Jaehong LIM, Suwon-si (KR); Chulmin CHO, Suwon-si (KR); Seok HEO, Suwon-si (KR)

(21) Appl. No.: 18/659,932

(22) Filed: May 9, 2024

(30) Foreign Application Priority Data
Jul. 13, 2023 (KR) 10-2023-0091111

(51) Int. Cl. G03F 7/00; G03F 7/16; G03F 7/32

(52) U.S. Cl. CPC G03F 7/70875; G03F 7/168; G03F 7/325; G03F 7/70033; G03F 7/70625

(57) ABSTRACT

A substrate processing method includes: performing a first post-exposure baking process on a photoresist layer that was previously exposed to for extreme ultraviolet (EUV) exposed to EUV; developing the photoresist layer using a first developing solution having a first temperature; performing a second post-exposure baking process on the photoresist layer; developing the photoresist layer using a second developing solution having a second temperature, higher than the first temperature; and forming a photoresist pattern by performing a hard baking process on the photoresist layer.

### CROSS-REFERENCE TO RELATED APPLICATION(S)

This application claims benefit of priority to Korean Patent Application No. 10-2023-0091111, filed on Jul. 13, 2023 in the Korean Intellectual Property Office, the disclosure of which is incorporated herein by reference in its entirety.

### BACKGROUND

Embodiments of the present disclosure relate to a substrate processing method and a substrate processing apparatus using the same.

In a manufacturing process of a semiconductor device, a photolithography process is used to form patterns of various shapes and structures. The photolithography process includes a coating process of coating a photoresist on a surface of a substrate to form a photoresist film, an exposure process of exposing the coated photoresist film to light, and a developing process of developing the exposed photoresist film to form a circuit pattern. As line widths and intervals of patterns are gradually refined, introduction of photolithography processes using shorter wavelengths, for example, extreme ultraviolet (EUV), is gradually increasing.

### SUMMARY

According to embodiments of the present disclosure, a substrate processing method capable of implementing improved photoresist pattern quality and a substrate processing apparatus using the same are provided.

According to embodiments of the present disclosure, a substrate processing method may be provided. The substrate processing method includes: performing a first post-exposure baking process on a photoresist layer that was previously exposed to extreme ultraviolet (EUV); developing the photoresist layer using a first developing solution having a first temperature; performing a second post-exposure baking process on the photoresist layer; developing the photoresist layer using a second developing solution having a second temperature, higher than the first temperature; and forming a photoresist pattern by performing a hard baking process on the photoresist layer.

According to embodiments of the present disclosure, a substrate processing method may be provided. The substrate processing method includes: forming a layer on a substrate; forming a photoresist layer on the layer; exposing the photoresist layer using an exposure mask; performing a first post-exposure baking process on the photoresist layer; developing the photoresist layer using a first developing solution having a first temperature; performing a second post-exposure baking process on the photoresist layer; developing the photoresist layer using a second developing solution having a second temperature different from the first temperature; forming a photoresist pattern by performing a hard baking process on the photoresist layer; and partially removing the layer by performing an etching process using the photoresist pattern as an etching mask.

According to embodiments of the present disclosure, a substrate processing method may be provided. The substrate processing method includes: performing a first post-exposure baking process on the photoresist layer; developing the photoresist layer using a first developing solution having a first temperature; developing the photoresist layer using a second developing solution having a second temperature different from the first temperature; and forming a photoresist pattern by performing a hard baking process on the photoresist layer.

According to embodiments of the present disclosure, a substrate processing apparatus may be provided. The substrate processing apparatus includes: a chamber including a processing space for processing a substrate; a substrate support unit including at least one body configured to support the substrate, while the substrate is loaded into the processing space; a tank configured to store a developing solution; a liquid supply unit including at least one body that is configured to supply the developing solution from the tank to the chamber; a heater configured to apply heat to at least one from among the tank, the liquid supply unit, and the substrate; and a temperature controller configured to control an operation of the heater, wherein the temperature controller is further configured to control a temperature of the developing solution to a first temperature and a second temperature, higher than the first temperature, by controlling a temperature of at least one from among the tank, the liquid supply unit, and the substrate by controlling the operation of the heater.

### BRIEF DESCRIPTION OF DRAWINGS

The above and other aspects, features, and advantages of embodiments of the present disclosure will be more clearly understood from the following detailed description, taken in conjunction with the accompanying drawings:

FIG. 1 is a plan view illustrating an apparatus for manufacturing a semiconductor apparatus according to example embodiments;

FIG. 2 is a diagram schematically illustrating a lithography apparatus according to example embodiments;

FIG. 3 is a cross-sectional view schematically illustrating a developing apparatus according to example embodiments;

FIGS. 4A to 4C are cross-sectional views schematically illustrating a developing apparatus according to example embodiments;

FIGS. 5A to 5C are diagrams for illustrating a substrate processing method according to example embodiments;

FIG. 6 is a flowchart illustrating a substrate processing method according to example embodiments; and

FIGS. 7 to 11 are schematic diagrams illustrating a substrate processing apparatus method according to example embodiments.

### DETAILED DESCRIPTION

Hereinafter, with reference to the accompanying drawings, non-limiting example embodiments of the present disclosure will be described.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

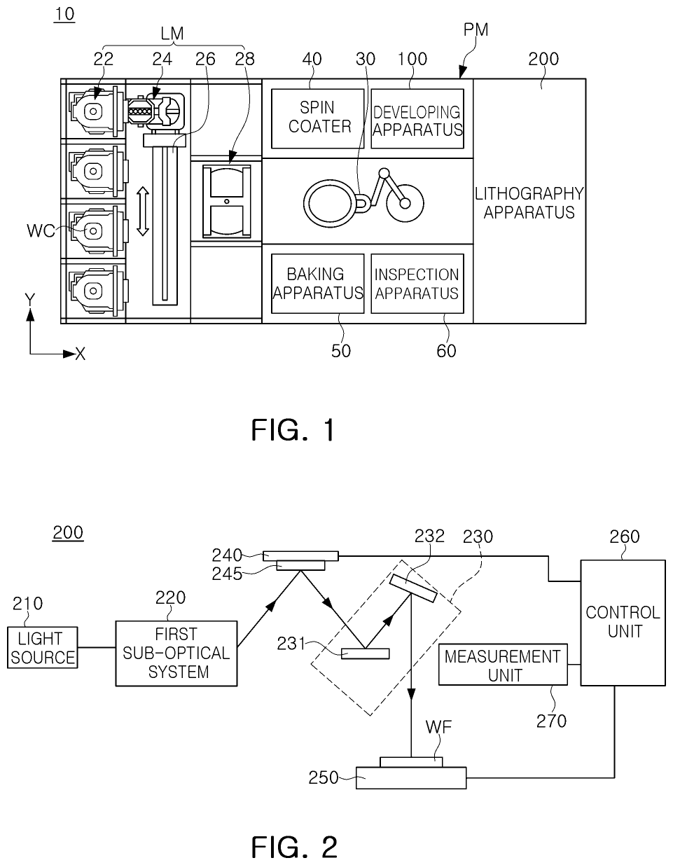

FIG. 1 is a plan view illustrating an apparatus for manufacturing a semiconductor apparatus according to example embodiments.

Referring to FIG. 1, a semiconductor device manufacturing apparatus 10 for manufacturing a semiconductor apparatus may include a substrate loading module LM and a substrate processing module PM. The substrate loading module LM and the substrate processing module PM may be disposed in a line in a first direction, for example, an X-direction. The substrate loading module LM may include a load port 22, an index robot 24, a transfer rail 26, and a buffer unit 28. The substrate processing module PM may include a plurality of apparatuses that perform a series of processes on substrates. The substrate processing module PM may include a transfer robot 30, a spin coater 40, a developing apparatus 100, a baking apparatus 50, an inspection apparatus 60, and a lithography apparatus 200.

In the substrate loading module LM, the load port 22 may be disposed on one side of the index robot 24 and the transfer rail 26. A plurality of the load port 22 may be arranged in a line along the transfer rail 26. The load port 22 may include a carrier WC capable of accommodating a substrate such as a wafer. The carrier WC may be transported from the outside and loaded into the load port 22, or may be unloaded from the load port 22 and transported to the outside.

The index robot 24 can move along the transport rail 26. The transport rail 26 may be disposed to extend along a second direction, perpendicular to a first direction, for example, along a Y-direction. The transfer rail 26 may provide a path for the index robot 24 to move. The index robot 24 may transfer a substrate accommodated in the carrier WC to the buffer unit 28. Alternatively, the index robot 24 may take out the substrate from the buffer unit 28 and accommodate the same in the carrier WC.

The buffer unit 28 may be disposed between the transfer rail 26 and the transfer robot 30. The buffer unit 28 may provide a buffer space in which a substrate transferred between the index robot 24 and the substrate processing module PM temporarily remains. One or more buffer slots in which a substrate is disposed may be provided inside the buffer unit 28. A substrate unloaded from the carrier WC by the index robot 24, or a substrate unloaded from the substrate processing module PM by the transfer robot 30 may be disposed in the buffer slot.

In the substrate processing module PM, the transfer robot 30 may take out the substrates from the buffer unit 28, and transfer the same to at least one from among the spin coater 40, the developing apparatus 100, the baking apparatus 50, the inspection apparatus 60, and the lithography apparatus 200. The transfer robot 30 may transfer, for example, a substrate on which a pre-exposure process has been performed in the spin coater 40 to the lithography apparatus 200, and take out the substrate on which the exposure process has been performed from the lithography apparatus 200 to be moved to other apparatuses, for example, the developing apparatus 100, the baking apparatus 50, and the inspection apparatus 60. Although the transfer robot 30 is illustrated as including a robot arm in the drawings, embodiments of the present disclosure are not limited thereto, and the transfer robot 30 may include other means capable of moving a substrate such as a conveyor belt, a transfer rail, or the like.

The spin coater 40 may form a coating layer by coating a coating material on the substrate. For example, the coating layer may include a photoresist layer. For example, the photoresist layer may be a chemical amplified resist. For example, the coating layer may include, in addition to the photoresist layer, any one from among an organic planarization layer disposed under the photoresist layer, an anti-reflective coating layer, an upper coating layer disposed on the photoresist layer, and combinations thereof.

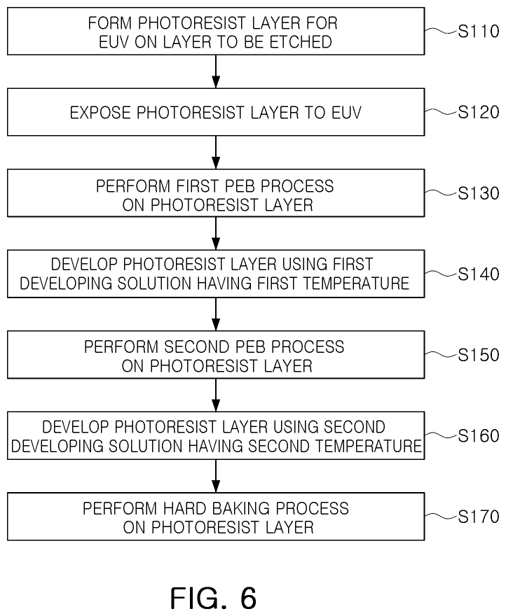

The developing apparatus 100 may perform a developing process on a substrate on which an exposure process has been completed by the lithography apparatus 200. The developing process may be a process for removing an exposed portion or an unexposed portion of the coating layer. The developing process may include spraying a developing solution onto a substrate and spinning the substrate to coat an entire surface of the substrate with the developing solution. An exposed portion or an unexposed portion of the coating layer may be removed by the developing process. For example, the developing solution may include an acetate-based material, an alkane-type organic solvent, and/or a ketone-type organic solvent. According to the substrate processing method according to example embodiments, the developing process may be performed a plurality of times. This will be described in more detail with reference to FIGS. 6 to 11 below.

The baking apparatus 50 may perform at least one from among a soft baking process, a post-exposure baking process, and a hard baking process. A specific structure of the baking apparatus 50 will be described in more detail with reference to FIG. 3 below. The soft baking process is also referred to as pre-baking, and may be performed after forming a coating layer on a substrate in the spin coater 40. The soft baking process may be a process for removing an organic solvent remaining in the coating layer, for example, a photoresist layer, and strengthening bonding between the coating layer and a wafer. The soft baking process may be performed at a relatively low temperature.

A post-exposure baking process may be a process for planarizing curves formed on a surface of the photoresist layer as light intensity becomes uneven due to standing waves formed during exposure. The post-exposure baking process may activate a photoactive compound (PAC) included in the photoresist layer, and thus, the curves formed on the photoresist layer may be reduced. According to the substrate processing method according to example embodiments, the post-exposure baking process may be performed a plurality of times. This will be described in more detail with reference to FIGS. 6 to 11 below.

A hard baking process may be a process for improving durability against etching and increasing adhesion to a substrate by curing the photoresist layer after exposure and developing processes are performed. Compared to the soft baking process, the hard baking process may be performed at a relatively high temperature.

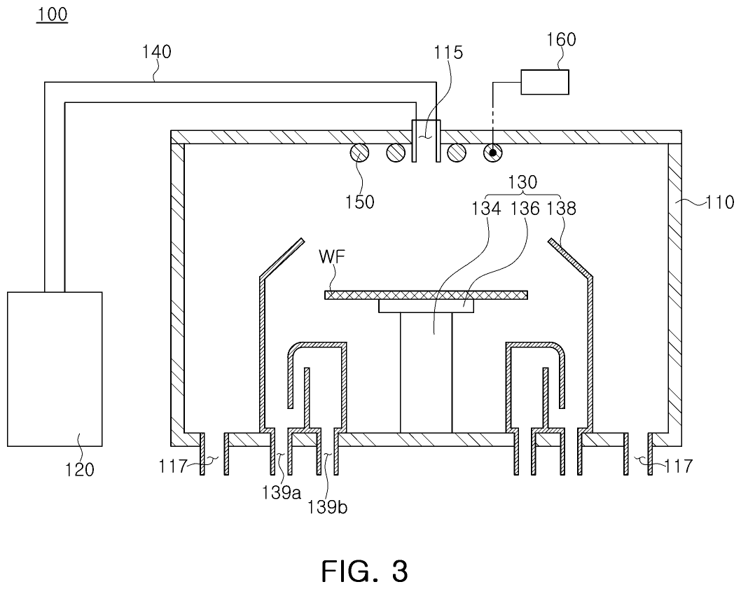

The lithography apparatus 200 may perform a lithography process using EUV as a light source. The lithography apparatus 200 may expose a photoresist layer applied on the substrate using EUV to correspond to a predetermined pattern image. EUV may have a wavelength within about 2 nm to about 50 nm, for example, about 13 nm to about 14 nm. Such light is also called as soft X-ray light. In some example embodiments, EUV having a wavelength of less than 11 nm may be used. For example, a wavelength in a range of 5 nm to 10 nm or 5 nm to 8 nm may be used. A detailed structure of the lithography apparatus 200 will be described in more detail with reference to FIG. 2 below.

The inspection apparatus 60 may be an apparatus inspecting a photoresist pattern after a developing process and/or a hard baking process. The inspection apparatus 60 may include, for example, an inspection apparatus such as an electron microscope such as a scanning electron microscope (SEM). The inspection apparatus 60 may measure a critical dimension (CD) of the photoresist pattern and determine whether or not there is a defect such as pattern collapse.

The type and number of apparatuses disposed in the substrate processing module PM may be variously changed in example embodiments. For example, the substrate processing module PM may further include a drying apparatus for drying a substrate, a cleaning apparatus for cleaning a rear surface of the substrate, or the like, in addition to the substrate processing apparatuses. The drying apparatus may be an apparatus that dries a remaining developing solution after a developing process is performed using a supercritical fluid and/or a subcritical fluid. The cleaning apparatus may be, for example, an apparatus that cleans the rear surface of the substrate after a soft baking process is performed.

FIG. 2 is a diagram schematically illustrating a lithography apparatus according to example embodiments.

Referring to FIG. 2, an example embodiment of the lithography apparatus 200 of the semiconductor device manufacturing apparatus 10 of FIG. 1 is described below. The lithography apparatus 200 is an apparatus for performing a photolithography process, and may include a light source 210, a first sub-optical system 220, a second sub-optical system 230, a mask stage 240, a wafer stage 250, a control unit 260 (e.g., a controller), and a measurement unit 270 (e.g., a sensor).

The light source 210 may generate and emit EUV having a high energy density within a wavelength range of several nanometers to several tens of nanometers. According to example embodiments, the light source 210 may generate and output EUV having a high energy density in, for example, a 13.5 nm wavelength band. The light source 210 may include a plasma-based light source, a synchrotron radiation light source, or the like. The plasma-based light source may be a light source that generates plasma and uses light emitted by the plasma, and may include a Laser-Produced Plasma (LPP) light source, Discharge-Produced Plasma (DPP), or the like. For example, when the light source 210 includes the plasma-based light source, a condensing mirror such as an elliptical mirror, a spherical mirror, or the like, for increasing the energy density of EUV incident to the first sub-optical system 220 may be further included in the light source 210.

The first sub-optical system 220 may include a plurality of mirrors. For example, the first sub-optical system 220 may include two or three mirrors. However, the number of mirrors included in the first sub-optical system 220 is not limited thereto. The first sub-optical system 220 may transmit EUV emitted by the light source 210 to a mask 245. The EUV emitted by the light source 210 may be reflected by mirrors included in the first sub-optical system 220 and may be incident on the mask 245 mounted on the mask stage 240. In an example embodiment, the first sub-optical system 220 may form EUV into a shape of a curved slit and make the same incident on the mask 245.

The mask 245 may be a reflective mask including a non-reflective region and/or an intermediate reflective region, along with a reflective region. The mask 245 may include a mask substrate formed of a low thermal expansion coefficient material (LTEM) such as quartz, and patterns including a reflective multilayer film for reflecting EUV on the mask substrate and an absorption layer formed on the reflective multilayer film. For example, the reflective multilayer film may have a structure in which molybdenum (Mo) layers and silicon (Si) layers are alternately stacked. The absorption layer may be formed of at least one from among TaN, TaNO, TaBO, Ni, Au, Ag, C, Te, Pt, Pd, and Cr. However, a material of the reflective multilayer film and a material of the absorption layer are not limited to the materials described above, and the absorption layer may be located on the non-reflective region and/or the intermediate reflective region described above.

The mask 245 may reflect EUV light incident through the first sub-optical system 220 and make the light incident on the second sub-optical system 230. For example, EUV that has passed through the first sub-optical system 220 may be structured according to the shape of the patterns of the reflective multilayer film and the absorption layer on the mask substrate and may be incident on the second sub-optical system 230. EUV may be structured to include at least secondary diffracted light based on the patterns. The structured EUV may be incident on the second sub-optical system 230 while holding the information of the pattern shape included in the mask 245, and may be irradiated onto a substrate WF such as a wafer through the second sub-optical system 230 to form an image corresponding to the pattern shape included in the mask 245. For example, the structured EUV may be irradiated in a predetermined pattern form onto a photoresist layer applied on the substrate WF.

The second sub-optical system 230 may include a plurality of mirrors. In FIG. 2, the second sub-optical system 230 is illustrated as including a first mirror 231 and a second mirror 232, but this is an example, and the second sub-optical system 230 may include three or more mirrors. In some example embodiments, the second sub-optical system 230 may include 4 to 8 mirrors. The second sub-optical system 230 may be controlled so that EUV reflected from the mask 245 is incident on an upper surface of the substrate WF at a predetermined angle. For example, the second sub-optical system 230 may adjust a path of EUV so that the EUV light is incident on the upper surface of the substrate WF at an incident angle of about 6 degrees.

The mask 245 may be seated on the mask stage 240, and the substrate WF may be seated on the wafer stage 250. The mask stage 240 and wafer stage 250 may be controlled by the control unit 260. In an initial state in which the mask 245 and the substrate WF are seated on the mask stage 240 and the wafer stage 250, respectively, when an upper surface of each of the mask 245 and the substrate WF is defined as an X-Y plane, each of the mask stage 240 and the wafer stage 250 may be moved by the control unit 260. In an example embodiment, the control unit 260 may rotate each of the mask stage 240 and the wafer stage 250 on the X-Y plane about a Z-axis, or rotate the same on a Y-Z plane or an X-Z plane about any one axis on the X-Y plane. By the movement of the mask stage 240 and/or the wafer stage 250 as described above, the mask 245 and/or the substrate WF may move or rotate along at least one from among the X-axis, Y-axis, and Z-axis.

The measurement unit 270 may measure a critical dimension and/or overlay error, or the like, of a plurality of patterns formed through exposure on the substrate WF. For example, the measurement unit 270 may include an electron microscope or an optical microscope such as a SEM, a Transmission Electron Microscope (TEM), or the like. The measurement unit 270 may measure critical dimensions, overlay errors, or the like, using image ellipsoidalization, spectroscopic image ellipsoidalization, or the like. Depending on the embodiment, the measurement unit 270 may be provided as a separate apparatus from the lithography apparatus 200.

FIG. 3 is a cross-sectional view schematically illustrating a developing apparatus according to example embodiments.

Referring to FIG. 3, an example embodiment of the developing apparatus 100 of the semiconductor device manufacturing apparatus 10 of FIG. 1 is described below. The developing apparatus 100 may include a chamber 110, a tank 120 storing a developing solution provided to the chamber 110, a liquid supply unit 140 supplying a developing solution from the tank 120 into the chamber 110, a substrate support unit 130 installed in the chamber 110 and fixing and rotating a substrate WF, which is a processing target, a substrate heating unit 150 (e.g., a heater) installed on the substrate WF in the chamber 110 and heating the substrate WF, and a temperature control unit 160 (e.g., a temperature controller) controlling the substrate heating unit 150. The developing apparatus 100 may be a substrate processing device that performs a developing process by providing a developing solution on the substrate WF.

The chamber 110 is a housing capable of providing a processing space in which a developing process for the substrate WF is performed, and may provide a sealed internal space. For example, the chamber 110 may be provided in a cylindrical or hexahedral shape with an internal space of a certain size. The chamber 110 may include a liquid inlet 115 for supplying a developing solution supplied from the tank 120 onto the substrate WF thereabove. In some example embodiments, another supply member, such as a shower head or nozzle, may be further disposed in the chamber 110, and the liquid inlet 115 or the liquid supply unit 140 may be connected to the supply member. The chamber 110 may be provided with a gate on one side, which is a passage for moving the substrate WF into the chamber 110 or removing the processed substrate WF out of the chamber 110. For example, an upper region of the chamber 110 may function as the gate, and the upper region may be opened while being separated from a lower region of the chamber 110. However, in example embodiments, a specific shape of the gate may be variously changed. A plurality of the liquid outlet 117 may be disposed on a bottom of the chamber 110. A developing solution used in the chamber 110 may be discharged externally through the plurality of the liquid outlet 117. The plurality of the liquid outlet 117 may be connected to an external discharge means, such as a discharge pump.

The substrate WF may be a substrate for manufacturing a semiconductor device, for example, a wafer. The substrate WF may include a semiconductor material, and may include a layer to be etched and an exposed photoresist layer on the layer to be etched. For example, the substrate WF may have a portion of a semiconductor device formed on the wafer.

The tank 120 may be installed outside the chamber 110 and may supply a developing solution into the chamber 110 through a pipe as the liquid supply unit 140. In the present embodiment, the tank 120 may store and supply the developing solution at a specific temperature, for example, room temperature in a range of about 20° C. to about 25° C. However, a shape of the tank 120, an installation method, a connection form with the chamber 110, and the like may vary in various example embodiments.

The liquid supply unit 140 may be a piping structure that delivers a developing solution from the tank 120 to the liquid inlet 115 of the chamber 110. The liquid supply unit 140 may have a form of, for example, a tube, line, pipe, or the like. In some example embodiments, an end portion of the liquid supply unit 140 may extend into an interior of the chamber 110.

The substrate supporter 130 may be disposed in a lower portion of a processing space within the chamber 110 to support a substrate WF fixed on an upper surface thereof. The substrate support unit 130 may be, for example, a spinner rotating the substrate WF. The substrate support unit 130 may include a support structure 134, a spin chuck 136 disposed on the support structure 134 to fix and rotate the substrate WF, and a cup portion 138 disposed around the substrate WF.

The support structure 134 may be comprising a slender member extending downwardly from a lower portion of the spin chuck 136. The support structure 134 may include a motor therein, and power from the motor may be transmitted to the spin chuck 136. For example, the support structure 134 may transmit a vertical movement in a longitudinal direction and a rotational movement about a central axis to the spin chuck 136.

The spin chuck 136 may rotate a substrate WF by fixing the same to an upper surface thereof. For example, the spin chuck 136 may fix the substrate WF by vacuum suction. The spin chuck 136 may rotate at a constant rotation speed and may rise or fall in a vertical direction when loading and unloading the substrate WF.

The cup portion 138 may collect a developing solution overflowing from an edge of a substrate WF and discharge the same. The cup portion 138 may have a bowl shape surrounding the substrate WF. The cup portion 138 may have an internal space of a certain size, an open top, and first discharge lines 139a and second discharge lines 139b at a bottom of the cup portion 138. The developing solution supplied to the substrate WF may be discharged externally along the first discharge lines 139a provided in a lower portion of the cup portion 138. Gas inside the chamber 110 may be discharged through the second discharge lines 139b. However, a shape of the cup portion 138 in FIG. 1 is illustrative, and may be changed into various shapes in example embodiments. For example, in some example embodiments, the second discharge lines 139b may be omitted.

The substrate heating unit 150 may be located above the substrate WF and the substrate support unit 130 within the chamber 110. The substrate heating unit 150 may overlap at least a portion of the substrate WF in a vertical direction. The substrate heating unit 150 may be configured to control a temperature of the developing solution supplied to the substrate WF by applying heat to the substrate WF. The substrate heating unit 150 may include a laser or light source, and may be used temporarily during a processing time. In some example embodiments, the substrate heating unit 150 may include, for example, a heating coil or a heating plate. For example, the substrate heating unit 150 may control a temperature of the developing solution supplied to the substrate WF within a range of about 20° C. to about 40° C.

The temperature control unit 160 may be configured to control a temperature and heating time of the substrate heating unit 150. For example, the temperature control unit 160 may control the substrate heating unit 150 to control the temperature of the developing solution to a first temperature in a first developing process, and control the temperature of the developing solution to a second temperature, higher than the first temperature, in a second developing process, among the plurality of developing processes described with reference to FIG. 6. In some example embodiments, the temperature control unit 160 may control the substrate heating unit 150 so that the substrate heating unit 150 operates during the second developing process without operating during the first developing process. The developing apparatus 100 may further include a control unit that controls the support structure 134, the tank 120, or the like. According to the developing apparatus 100 of this embodiment, the temperature of the developing solution may be controlled during the developing process by including the substrate heating unit 150 disposed on the substrate support unit 130.

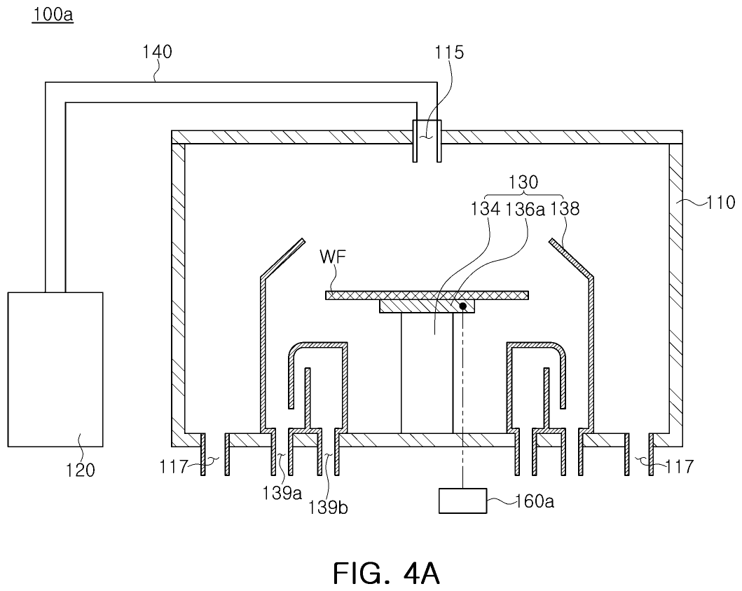

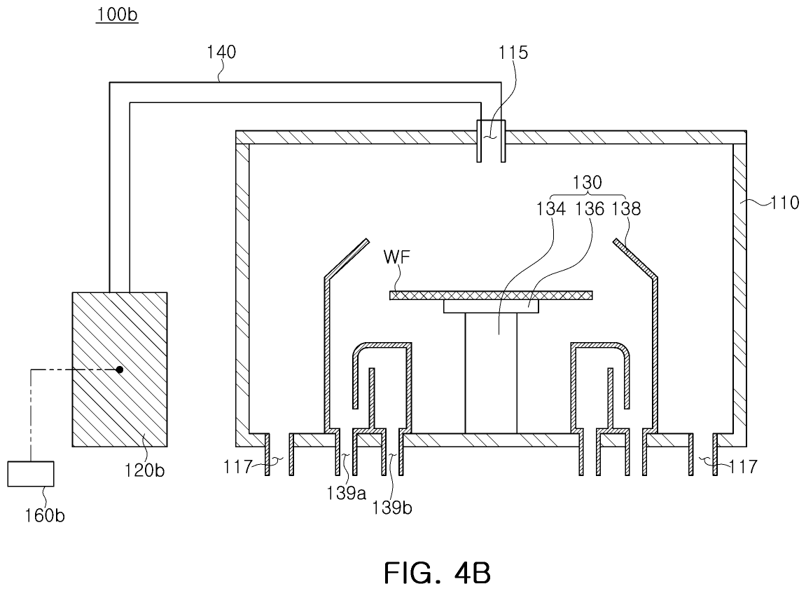

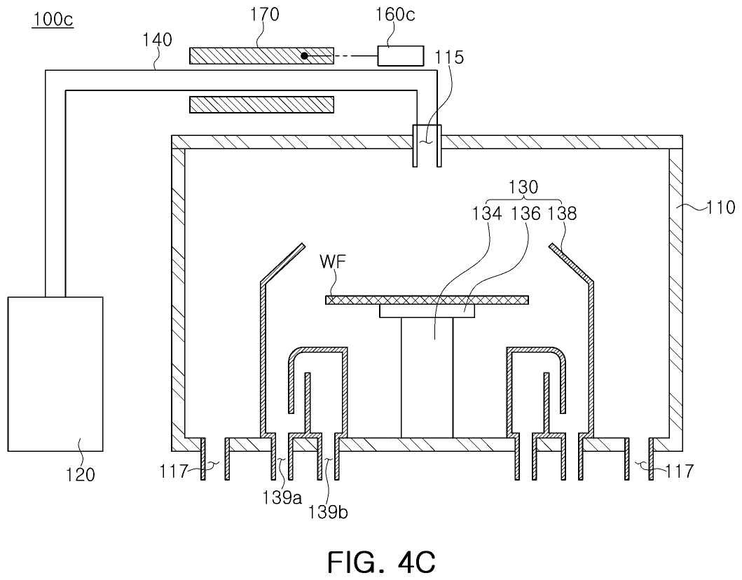

FIGS. 4A to 4C are cross-sectional views schematically illustrating a developing apparatus according to example embodiments.

Referring to FIG. 4A, unlike the example embodiment of FIG. 3, a developing apparatus 100a may not include a substrate heating unit 150. A substrate support unit 130 of the developing apparatus 100a may include a spin chuck 136a configured to generate heat, and the developing apparatus 100a may include a temperature control unit 160a controlling a temperature of the spin chuck 136a.

The spin chuck 136a may be disposed below a substrate WF and overlap at least a portion of the substrate WF in a vertical direction. The spin chuck 136a may be a heating spin chuck configured to control a temperature of a developing solution supplied to the substrate WF by applying heat to the substrate WF. The spin chuck 136a may include, for example, a heating coil or a heating plate. For example, the spin chuck 136a may control the temperature of the developing solution supplied to the substrate WF in a range of about 20° C. to about 40° C.

The temperature control unit 160a may be configured to control a temperature and heating time of the spin chuck 136a. For example, the temperature control unit 160a may control the spin chuck 136a, to control a temperature of the developing solution to a first temperature in a first developing process, and a temperature of the developing solution to a second temperature, higher than the first temperature, in a second developing process, among the plurality of developing processes described with reference to FIG. 6.

Referring to FIG. 4B, unlike the embodiment of FIG. 3, a developing apparatus 100b may not include the substrate heating unit 150. A tank 120b of the developing apparatus 100b may be configured to heat a developing solution thereinside, and the developing apparatus 100b may include a temperature control unit 160b that controls a temperature of the tank 120b.

The tank 120b may be a heating tank or a cooling tank configured to control a temperature of the developing solution supplied into the chamber 110 by applying heat to or cooling the developing solution stored therein. The tank 120b may include, for example, a heating coil or a heating jacket. For example, the tank 120b may control the temperature of the developing solution supplied into the chamber 110 within a range of about 20° C. to about 40° C.

The temperature control unit 160b may be configured to control a temperature and heating time of the tank 120b. For example, the temperature control unit 160b may control the tank 120b, to control a temperature of the developing solution to a first temperature in a first developing process and control the temperature of the developing solution to a second temperature, higher than the first temperature, in a second developing process, among the plurality of developing processes described with reference to FIG. 6.

Referring to FIG. 4C, unlike the embodiment of FIG. 3, a developing apparatus 100c may not include a substrate heating unit 150, and may include a supply path heating unit 170 and a temperature control unit 160c controlling a temperature of the supply path heating unit 170.

The supply path heating unit 170 may be a heating unit or cooling unit configured to adjust a temperature of the developing solution supplied into the chamber 110 by applying heat to the developing solution supplied into the chamber 110 from the tank 120 or by cooling the developing solution. The supply path heating unit 170 may include, for example, a heating coil or an in-line heater. For example, the supply path heating unit 170 may control the temperature of the developing solution supplied into the chamber 110 within a range of about 20° C. to about 40° C.

The temperature control unit 160c may be configured to control a temperature and heating time of the supply path heating unit 170. For example, the temperature control unit 160c may control the supply path heating unit 170 to control the temperature of the developing solution to a first temperature in a first developing process and the temperature of the developing solution to a second temperature, higher than the first temperature, in a second developing process, among the plurality of developing processes described with reference to FIG. 6.

In some example embodiments, two or more of the substrate heating unit 150, spin chuck 136a, tank 120b, and supply path heating unit 170 described above with reference to the embodiments of FIGS. 3 to 4C may be installed in combination in one developing apparatus.

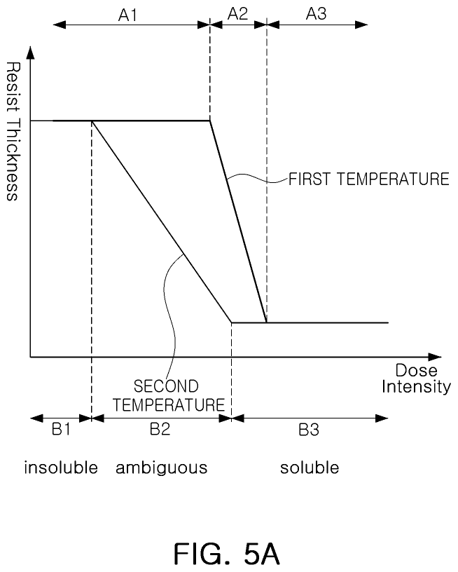

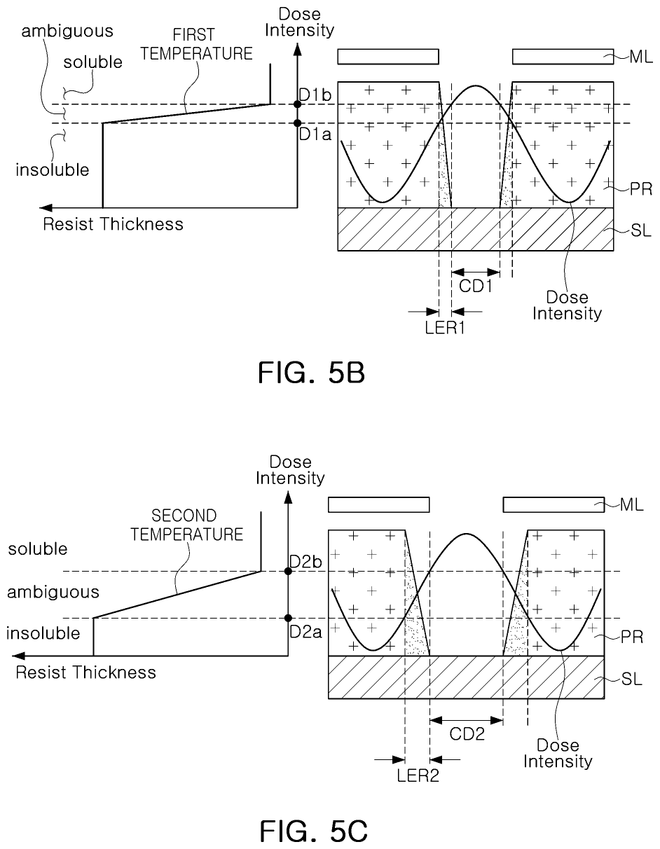

FIGS. 5A to 5C are diagrams for illustrating a substrate processing method according to example embodiments.

Referring to FIG. 5A, a photoresist contrast curve indicating a thickness of the photoresist layer after a developing process is illustrated in cases in which a temperature of a developing solution is a first temperature and a second temperature. At each temperature, a relationship of a resist thickness, that is, a thickness of the photoresist, according to dose intensity is illustrated, from which dissolution characteristics of the photoresist are shown. The second temperature may be higher than the first temperature. For example, the first temperature may be room temperature or a temperature similar thereto, and the second temperature may be a temperature, higher than the first temperature.

When the developing solution is at the first temperature, the photoresist layer may include a first region A1, which is insoluble, in a section in which exposure energy is relatively low. As the exposure energy increases, the photoresist layer may include a second region A2, which is an ambiguous region, in the second region A2, the thickness of the photoresist layer may decrease as exposure energy increases. An inclination at which the thickness of the photoresist layer decreases may be relatively large compared to the second temperature. As the exposure energy increases, the photoresist layer may be completely dissolved and removed in a third region A3, which is soluble. In the case of the first temperature, high exposure energy is required for dissolution, but the second region A2 may be relatively narrow. Accordingly, the critical dimension can be relatively small and the contrast characteristics can be excellent.

When the developing solution is at a second temperature, the photoresist layer may include a first region B1 (insoluble), a second region B2 (ambiguous), and a third region B3 (soluble). When the developing solution is at the relatively high second temperature, it may be dissolved even with low exposure energy, and the second region B2 may be relatively widened. In addition, an inclination at which the thickness of the photoresist layer decreases in the second region B2 may be smaller than the slope at the first temperature. Accordingly, a critical dimension may be relatively large and contrast characteristics may be poor.

Referring to FIG. 5B, a photoresist contrast curve and a photoresist layer PR, that is developed, are illustrated together for the first temperature. The photoresist contrast curve described above can be applied in horizontal and vertical directions with respect to the photoresist layer PR.

The photoresist layer PR may be formed on a substrate structure SL, exposed using an exposure mask ML, and then developed at the first temperature. The substrate structure SL may include a substrate and a layer to be etched on the substrate. The exposure energy may have a form similar to a standing wave as illustrated in FIG. 5B. Among exposed portions corresponding to an opening of the exposure mask ML, the photoresist layer PR may be dissolved and removed in a region in which the exposure energy is equal to or higher than a first dose D1b. Thereby, a first critical dimension CD1 can be determined.

At an edge of the exposed portion overlapping the opening and illustrated with different hatching, the exposure energy may be a value between the first dose D1b and a second dose D1a, and the photoresist layer PR may have an inclination according to the photoresist contrast curve and a portion thereof may dissolve. Accordingly, a pattern having first line edge roughness (LER1) can be implemented.

Referring to FIG. 5C, a photoresist contrast curve and a photoresist layer PR, that is developed, are illustrated together for the second temperature.

In an exposed portion corresponding to an opening of an exposure mask ML, since exposure energy is greater than a third dose D2b, the photoresist layer PR may be completely dissolved and removed. Accordingly, a critical dimension of a photoresist pattern may be determined to have a second critical dimension CD2, greater than a first critical dimension CD1. The second critical dimension CD2 may correspond to or be close to a target critical dimension.

In a weak exposed region, which is a region adjacent to the opening and illustrated with different hatching than a non-exposed region, exposure energy may be a value between the third dose D2b and a fourth dose D2a, and the photoresist layer PR may have an inclination according to the photoresist contrast curve and may only partially be dissolved. Accordingly, a pattern having second line edge roughness (LER2), greater than the first line edge roughness (LEF1), may be implemented.

FIG. 6 is a flowchart illustrating a substrate processing method according to example embodiments.

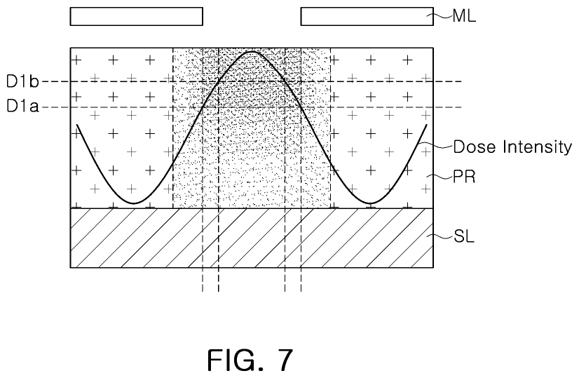

FIGS. 7 to 11 are schematic diagrams illustrating a substrate processing apparatus method according to example embodiments. FIGS. 7 to 11 illustrate a portion of the first dose D1b, the second dose D1a, the third dose D2b, and the fourth dose D2a described above with reference to FIGS. 5B and 5C.

Referring to FIGS. 6 and 7, a photoresist layer PR for EUV may be formed on a layer to be etched of a substrate structure SL (operation S110), the photoresist layer PR may be exposed to EUV (operation S120), and a first post-exposure baking (PEB) process may be performed on the photoresist layer PR (operation S130).

First, a layer to be etched may be formed on the substrate structure SL, and a photoresist layer PR may be formed on the layer to be etched. The photoresist layer PR may be formed on the layer to be etched using, for example, the spin coater 40 described above with reference to FIG. 1. The photoresist layer PR may be a photosensitive polymer material of which chemical properties are changed by exposure to EUV having a wavelength of about 13.5 nm, or less than about 11 nm. For example, the photoresist layer PR may include a (meth)acrylate-based polymer. The (meth)acrylate-based polymer may be an aliphatic (meth)acrylate-based polymer, for example, polymethylmethacrylate (PMMA), poly(t-butylmethacrylate, poly(methacrylic acid), poly(norbornylmethacrylate), binary or terpolymer of repeating units of the (meth)acrylate-based polymers, described above, or a combination thereof. The photoresist layer PR may be a polymer having a protective group, that can be deprotected by exposure, bonded to each repeating unit. The protective group is a functional group that can be decomposed by acid, and may be selected from a group consisting of, for example, tert-butoxycarbonyl(t-BOC), isonobonyl, 2-methyl-2-adamantyl, 2-ethyl-2-adamantyl, 3-tetrahydrofuranyl, 3-oxocyclohexyl, γ-butyllactone-3-yl, mevaloniclactone, γ-butyrolactone-2-yl, 3-methyl-γ-butyrolactone-3-yl, 2-tetrahydropyranyl, 2-tetrahydrofuranyl, 2,3-propylenecarbonate-1-yl, 1-methoxyethyl, 1-ethoxyethyl, 1-(2-methoxyethoxy) ethyl, 1-(2-acetoxyethoxy)ethyl), t-buthoxycarbonylmethyl, methoxymethyl, ethoxymethyl, trimethoxysilyl, and triethoxysilyl, but an example embodiment thereof is not limited thereto.

Next, a soft baking process may be performed on the photoresist layer PR. The soft baking process may be performed at, for example, about 80° C. to about 130° C.

Next, in the lithography apparatus 200 as described above with reference to FIG. 2, the photoresist layer PR may be irradiated with EUV using an exposure mask ML. Accordingly, EUV may be irradiated onto a region including a region corresponding to an opening of the exposure mask ML.

Next, a first PEB process may be performed in a baking apparatus 50 as described above with reference to FIG. 1. The first PEB process may be performed at a temperature of, for example, about 100° C. to about 250° C. Condensation and diffusion occur by the first PEB process, so that curves due to standing waves generated at an interface between an exposed portion irradiated with EUV and an unexposed portion not irradiated with EUV may be alleviated.

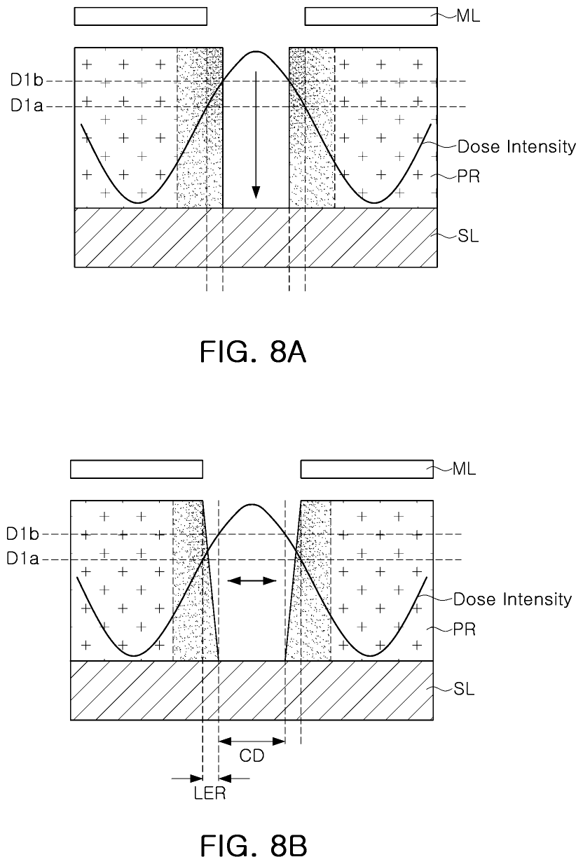

Referring to FIGS. 6, 8A, and 8B, a photoresist layer PR may be developed using a first developing solution at a first temperature (operation S140), and the present process may be referred to as a first developing process.

The first developing process may be performed in the developing apparatus described above with reference to FIGS. 3 to 4C. A stack structure of the substrate structure SL and the photoresist layer PR may be loaded into the chamber 110 of FIG. 3 and fixed on the substrate support unit 130. A spin chuck 136 may be rotated, and a first developing solution may be supplied onto the substrate structure SL. The first developing solution may be, for example, a non-polar organic solvent. The first developing solution may selectively remove a soluble region of the photoresist layer PR. For example, the first developing solution may include aromatic hydrocarbons, cyclohexane, cyclohexanone, acyclic or cyclic ethers, acetates, propionates, butyrates, lactates, or a combination thereof. For example, as the first developing solution, n-butyl acetate (nBA), propylene glycol methyl ether (PGME), propylene glycol methyl ether acetate (PGMEA), γ-butyrolactone (GBL), isopropanol (IPA), or the like may be used.

The first temperature may range from about 30% to about 150% of room temperature. The first temperature may be, for example, in a range of about 10° C. to about 25° C. The first temperature may be lower than a second temperature of a second developing process performed subsequently. A developing time may range from several tens of seconds to several minutes. The first temperature may be controlled by at least one from among temperature control units 160, 160a, 160b, and 160c which control at least one from among the substrate heating unit 150, the spin chuck 136a, the tank 120b, and the supply path heating unit 170, described above with reference to the embodiments of FIGS. 3 to 4C. After a developing process is performed, the stack structure may be unloaded from the chamber 110 of FIG. 3.

Dissolution in the developing process may first proceed in a vertical direction as illustrated in FIG. 8A and then proceed in a horizontal direction as illustrated in FIG. 8B according to time. As illustrated in FIG. 8A, first, the photoresist layer PR may be dissolved in a vertical direction in a region in which the exposure energy is greater than the first dose D1b. Next, as illustrated in FIG. 8B, in a region in which the exposure energy is greater than the second dose D1a, the photoresist layer PR may have an inclination on a side surface thereof and be dissolved in a horizontal direction. Due to the first developing process, the photoresist layer PR may have a first critical dimension CD and first line edge roughness LER. After the first developing process is performed, the line edge roughness characteristic may be excellent, but the critical dimension may be relatively smaller than a target dimension.

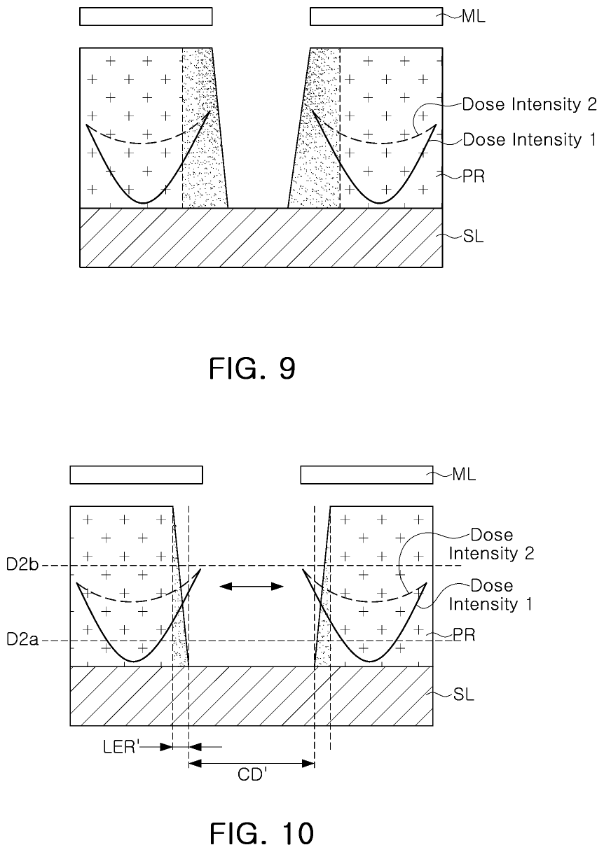

Referring to FIGS. 6 and 9, a second PEB process may be performed on a photoresist layer PR (operation S150).

The second PEB process may be performed in the same apparatus as the first PEB process, but an example embodiment thereof is not limited thereto. The second PEB process may be performed at a temperature lower than a temperature of the first PEB process, for example, within a temperature range of about 50% to about 80% of the temperature of the first PEB process. The second PEB process may be performed at a temperature of, for example, about 50° C. to about 150° C.

As illustrated in FIG. 9, exposure energy in the photoresist layer PR may be changed from a first intensity (Dose Intensity 1) to a second intensity (Dose Intensity 2) by the second PEB process. The exposure energy in the photoresist layer PR may be blurred to have a profile that locally increases in a region adjacent to a sidewall of the photoresist layer PR. Exposure energy may be relatively uniform in a region adjacent to the sidewall. This may be because the non-uniform exposure energy of the region adjacent to the sidewall of the photoresist layer PR is diffused and a complete crosslinking reaction is suppressed, by supplying thermal energy through the second PEB process. Since a region corresponding to a center of the opening of the exposure mask ML is removed by the first PEB process, diffusion can be efficiently performed in the region adjacent to the sidewall in the present operation.

Referring to FIGS. 6 and 10, a photoresist layer PR may be developed using a second developing solution at a second temperature (operation S160), and this process may be referred to as a second developing process.

The second developing process may be performed in the same apparatus as the first developing process, and regarding the apparatus, the description of the first developing process may be equally applied. However, in some example embodiments, the second developing process may be performed in an apparatus, different from an apparatus of the first developing process. The second developing solution may include the same material as or a different material from the first developing solution.

The second temperature may be higher than the first temperature, and may be within a range of about 50% to about 200% of room temperature. The second temperature may be, for example, within a range of about 20° C. to about 40° C. A developing time may range from several tens of seconds to several minutes. The second temperature may be controlled by at least one from among the temperature control units 160, 160a, 160b, and 160c controlling at least one from among the substrate heating unit 150, the spin chuck 136a, the tank 120b, and the supply path heating unit 170, described above with reference to the embodiments of FIGS. 3 to 4C.

As illustrated in FIG. 10, as a region in which an exposure energy is greater than a fourth dose D2a increases, dissolution may be mainly performed on a sidewall of the photoresist layer PR, and accordingly, a critical dimension may be increased to a second critical dimension CD′. The second critical dimension CD′ may be adjusted by controlling a developing time in this operation. Since the exposure energy is uniformly changed in the region adjacent to the sidewall by the second PEB process, after the second developing process is performed, line edge roughness characteristic may be the same as or improved second line edge roughness LER′ after the first PEB process. As described above, after the second developing process, the line edge roughness characteristics may be the same or improved, and the critical dimension can be increased to a target dimension. Therefore, compared to the case of being developed only at the first temperature described above with reference to FIG. 5B, a critical dimension may be secured, and compared to the case of being developed only at the second temperature described above with reference to FIG. 5C, contrast characteristics such as line edge roughness characteristics may be improved.

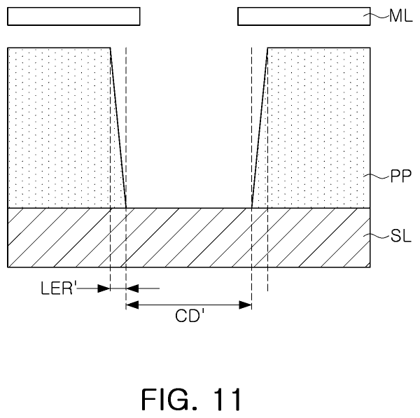

Referring to FIGS. 6 and 11, a hard baking process may be performed on the photoresist layer PR (operation S170).

The hard baking process may be performed in the same apparatus as the second PEB process, but an example embodiment thereof is not limited thereto. The hard baking process may be performed at a lower temperature than a temperature of the soft baking process. By the hard baking process, the photoresist layer PR may be cured to form a photoresist pattern PP. A size of a second critical dimension CD′ of the photoresist pattern PP may be, for example, 30 nm or less, e.g., within a range of about 3 nm to about 30 nm.

Subsequently, patterns may be formed by partially removing the layer to be etched by performing an etching process on the layer to be etched using a photoresist pattern PP.

As set forth above, a substrate processing method capable of realizing improved photoresist pattern quality by performing multiple developing processes and multiple baking processes at different temperatures and a substrate processing apparatus using the same may be provided.

According to embodiments, the controllers (e.g., the control unit 260, and the temperature control units 160, 160a, 160b, and 160c) may include at least one processor and memory storing computer instructions. The computer instructions may be configured to, when executed by the at least one processor, cause the controller to perform its functions. According to embodiments, any number of the controllers may be integrated together as a single controller or may be provided as separate controllers. According to embodiments, one or more controllers may be configured to control the semiconductor device manufacturing apparatus 10 of FIG. 1 to perform its functions, including the substrate processing method described above with reference to FIG. 6.

The various and advantageous advantages and effects of embodiments of the present disclosure are not limited to the above description, and may be more easily understood in the course of describing specific example embodiments of the present disclosure. While example embodiments have been shown and described above, it will be apparent to those skilled in the art that modifications and variations could be made without departing from the scope of the present disclosure.

What is claimed is:

1. A substrate processing method, comprising:
performing a first post-exposure baking process on a photoresist layer that was previously exposed to extreme ultraviolet (EUV);
developing the photoresist layer using a first developing solution having a first temperature;
performing a second post-exposure baking process on the photoresist layer;
developing the photoresist layer using a second developing solution having a second temperature, higher than the first temperature; and
forming a photoresist pattern by performing a hard baking process on the photoresist layer.

2. The substrate processing method of claim 1, wherein after the developing the photoresist layer using the first developing solution, the photoresist layer has a first critical dimension, and
after the developing the photoresist layer using the second developing solution, the photoresist layer has a second critical dimension greater than the first critical dimension.

3. The substrate processing method of claim 1, wherein the performing the first post-exposure baking process, the developing the photoresist layer using the first developing solution, the performing the second post-exposure baking process, and the developing the photoresist layer using the second developing solution are sequentially performed.

4. The substrate processing method of claim 1, wherein the first post-exposure baking process is performed at a third temperature, and the second post-exposure baking process is performed at a fourth temperature, lower than the third temperature.

5. The substrate processing method of claim 4, wherein the fourth temperature is within a range of 50° C. to 150° C.

6. The substrate processing method of claim 1, wherein the first temperature is within a range of 10° C. to 25° C.

7. The substrate processing method of claim 1, wherein the second temperature is within a range of 20° C. to 40° C.

8. The substrate processing method of claim 1, wherein after developing the photoresist layer using the first developing solution, the photoresist layer has a first line edge roughness, and
after developing the photoresist layer using the second developing solution, the photoresist layer has a second line edge roughness, equal to or smaller than the first line edge roughness.

9. The substrate processing method of claim 1, wherein the first developing solution and the second developing solution are a same material.

10. The substrate processing method of claim 1, wherein the forming the photoresist layer using the first developing solution and the developing the photoresist layer using the second developing solution are performed within a same chamber.

11. A substrate processing method, comprising:
forming a layer on a substrate;
forming a photoresist layer on the layer;
exposing the photoresist layer using an exposure mask;
performing a first post-exposure baking process on the photoresist layer;
developing the photoresist layer using a first developing solution having a first temperature;
performing a second post-exposure baking process on the photoresist layer;
developing the photoresist layer using a second developing solution having a second temperature different from the first temperature;
forming a photoresist pattern by performing a hard baking process on the photoresist layer; and
partially removing the layer by performing an etching process using the photoresist pattern as an etching mask.

12. The substrate processing method of claim 11, wherein the second temperature is higher than the first temperature.

13. The substrate processing method of claim 12, wherein the first temperature is within a range of 30% to 150% of room temperature, and the second temperature is within a range of 50% to 200% of room temperature.

14. The substrate processing method of claim 11, wherein the first post-exposure baking process is performed at a third temperature, and the second post-exposure baking process is performed at a fourth temperature,
wherein the fourth temperature is within a range of 50% to 80% of the third temperature.

15. The substrate processing method of claim 11, wherein after the developing the photoresist layer using the first developing solution, the photoresist layer has a first critical dimension; and
after the developing the photoresist layer using the second developing solution, the photoresist layer has a second critical dimension greater than the first critical dimension.

16. The substrate processing method of claim 11, wherein the exposing the photoresist layer comprises irradiating extreme ultraviolet (EUV) onto the photoresist layer.

17. A substrate processing method, comprising:
performing a first post-exposure baking process on a photoresist layer;
developing the photoresist layer using a first developing solution having a first temperature;
developing the photoresist layer using a second developing solution having a second temperature different from the first temperature; and
forming a photoresist pattern by performing a hard baking process on the photoresist layer.

18. The substrate processing method of claim 17, wherein after the developing the photoresist layer using the first developing solution, the photoresist layer has a first critical dimension, and
after the developing the photoresist layer using the second developing solution, the photoresist layer has a second critical dimension greater than the first critical dimension.

19. The substrate processing method of claim 17, wherein after developing the photoresist layer using the first developing solution, the photoresist layer has a first line edge roughness, and
after developing the photoresist layer using the second developing solution, the photoresist layer has a second line edge roughness, equal to or smaller than the first line edge roughness.

20. The substrate processing method of claim 17, wherein the second temperature is higher than the first temperature.
